(19) United States
(12) Patent Application Publication
(10) Pub. No.: US 2011/0279747 A1
(43) Pub. Date: Nov. 17, 2011

(54) DISPLAY PANEL UNIT AND ELECTRONIC DEVICE

(75) Inventors: JUN SAIKI, Osaka (JP); MASAMI FUKUHARA, Osaka (JP)

(73) Assignee: PANASONIC CORPORATION, Osaka (JP)

(21) Appl. No.: 13/103,213

(22) Filed: May 9, 2011

(30) Foreign Application Priority Data
May 10, 2010 (JP) 2010-107831

(51) Int. Cl. G02F 1/1333; H05K 7/00

(52) U.S. Cl. 349/58; 361/807

(57) ABSTRACT

The display panel unit includes a display panel, a panel-shaped member having a portion of which an outside size is larger than that of the display panel, a metal frame having a first housing section configured to house the display panel and a second housing section configured to house the panel-shaped member with the panel-shaped member stacked on the display panel. The metal frame has a bottom portion and a side wall portion configured to rise from an edge of the bottom portion, and is box-shaped so that an upper side of the metal frame is open, and the side wall portion is formed to be step-shaped so that an upper portion of the side wall portion protrudes outward. In an internal space formed by the bottom wall portion and the side wall portion of the metal frame, the first housing section is defined by a space formed by the bottom wall portion and a portion of the side wall potion other than the upper portion, and the second housing section is defined by a space other than the first housing section.

### BACKGROUND

1. Technical Field

The technical field relates to a display panel unit in which a display panel and related members are integral, and an electronic device provided with the display panel unit.

2. Related Art

Electronic devices such as digital cameras occasionally have liquid crystal display panel units for displaying various types of information. JP-A-2008-281835 discloses such a liquid crystal display panel unit. The liquid crystal display panel unit (a liquid crystal display module unit) disclosed in JP-A-2008-281835 has a liquid crystal display panel, a backlight having a plurality of optical films, and a frame-shaped case that can house the liquid crystal display panel and the backlight with them stacked.

In recent electronic devices, a touch panel is occasionally disposed on a front surface of a liquid crystal display panel. In this case, the touch panel and the liquid crystal display panel should be accurately aligned in a process of manufacture of the electric device. However, in the liquid crystal display panel unit having a structure disclosed in JP-A-2008-281835, in order to accurately align the touch panel on the front surface of the liquid crystal display panel, a jig or the like should be used, and thus assembly is not easy.

### SUMMARY

It is an object to provide a display panel unit of which assembly is easy and quality is not deteriorated even when a touch panel is disposed on a front surface of a display panel, and an electronic device provided with the display panel unit.

In a first aspect, there is provided a display panel unit. The display panel unit includes a display panel, a panel-shaped member having a portion of which an outside size is larger than that of the display panel, a metal frame having a first housing section configured to house the display panel and a second housing section configured to house the panel-shaped member with the panel-shaped member stacked on the display panel. The metal frame has a bottom portion and a side wall portion configured to rise from an edge of the bottom portion, and is box-shaped so that an upper side of the metal frame is open, and the side wall portion is formed to be step-shaped so that an upper portion of the side wall portion protrudes outward. In an internal space formed by the bottom wall portion and the side wall portion of the metal frame, the first housing section is defined by a space formed by the bottom wall portion and a portion of the side wall potion other than the upper portion, and the second housing section is defined by a space other than the first housing section.

In a second aspect, there is provided an electronic device having the display panel unit according to the first aspect.

According to the above aspects, the second housing section configured to house the related member stacked on the display panel is provided to the frame in addition to the first housing section configured to house the display panel. Thus, the panel-shaped member can be positioned (aligned) at the predetermined position with respect to the display panel by merely disposing the related member in the second housing section. Therefore, a jig or the like does not have to be used for the positioning or alignment, and assembly of the display panel unit becomes easy.

### BRIEF DESCRIPTION OF DRAWINGS

FIGS. 1A to 1F are six views showing a digital camera according to an embodiment;

FIG. 2 is a first exploded perspective view showing the digital camera according to the embodiment;

FIG. 3 is a second exploded perspective view showing the digital camera according to the embodiment;

FIG. 4 is a third exploded perspective view showing the digital camera according to the embodiment;

FIGS. 5A and 5B are horizontal cross sectional views showing the digital camera according to the embodiment:

FIGS. 6A and 6B are vertical cross sectional views showing the digital camera according to the embodiment;

FIGS. 7A to 7C are exploded perspective views showing a liquid crystal display panel unit according to the embodiment;

FIGS. 8A and 8B are horizontal cross sectional views showing the liquid crystal display panel unit according to the embodiment;

FIG. 9 is a horizontal enlarged cross sectional view showing a left end of the liquid crystal display panel unit according to the embodiment;

FIGS. 10A and 10B are vertical cross sectional views showing the liquid crystal display panel unit according to the embodiment;

FIG. 11 is an exploded perspective view showing a backlight of the liquid crystal display panel unit according to the embodiment; and

FIG. 12 is a horizontal enlarged cross sectional view showing right and left ends of a conventional liquid crystal display panel unit.

### DETAILED DESCRIPTION OF PREFERRED EMBODIMENTS

Hereinafter, an embodiment will be described with reference to the attached drawings.

### 1. External Appearance

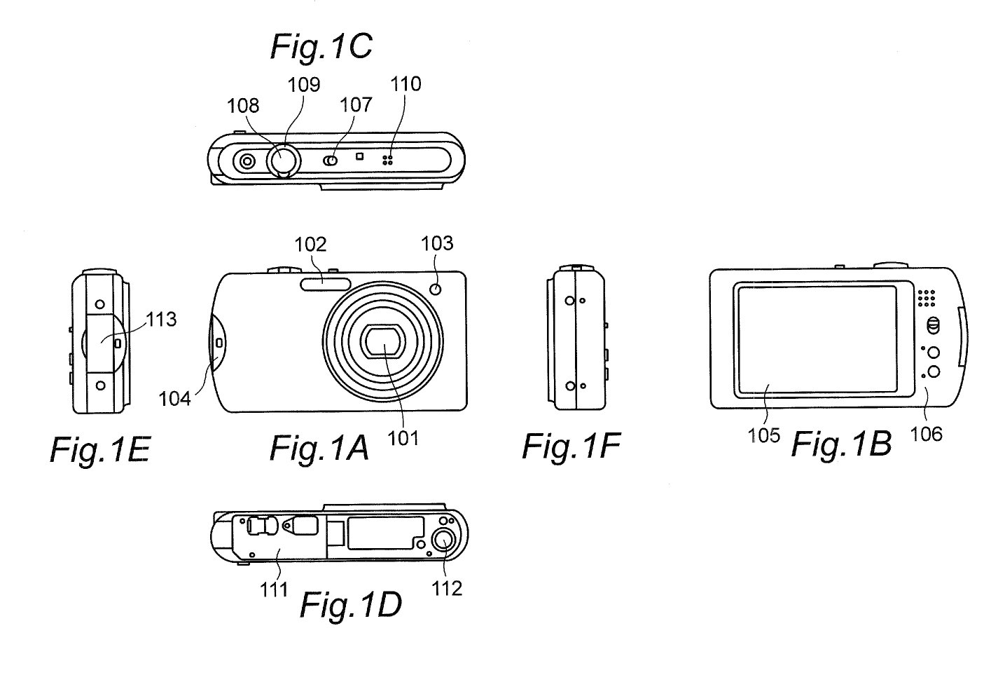

A digital camera according to the embodiment will be described in detail by way of example. FIGS. 1A to 1F are six views showing the digital camera according to the embodiment. The digital camera is one example of an electronic device. FIG. 1A is a front view, and FIG. 1B is a rear view. FIG. 1C is a top view, and FIG. 1D is a bottom view. FIG. 1E is a left side view, and FIG. 1F is a right side view. In this description, “right” and “left” mean right and left when the digital camera is viewed from the front.

As shown in FIG. 1A, a lens barrel 101 is disposed on a front surface of the digital camera. The lens barrel 101 guides subject light to an imaging device in the digital camera, and includes a plurality of optical members such as a focus lens, a zoom lens, and a diaphragm. The lens barrel 101 extends at the time of using the digital camera so as to protrude from a surface of a case, but retracts at the time of non-use of the digital camera to be housed in the case. As a result, miniaturization of the digital camera is realized.

A flash 102 and an AF auxiliary light lamp 103 are disposed on the front surface of the digital camera. The flash 102 emits a flash of light to compensate for deficiency of a quantity of photography light in photography in a dark place. The AF auxiliary light lamp 103 emits auxiliary light in order to perform an autofocus operation smoothly in a dark place.

A strap attachment hanger 104 to which a strap is attached is provided to a left end on the front surface of the digital camera. A small-sized electronic device such as the digital camera that is premised on being carried around is in danger of being dropped. The attachment of the strap to the strap attachment hanger 104 can reduce this danger.

As shown in FIG. 1B, a liquid crystal display panel 105 is disposed on the rear surface of the digital camera. The liquid crystal display panel 105 occupies a large space on the rear surface of the digital camera. Photography images and various operation screens are displayed on the liquid crystal display panel 105. A touch panel is arranged on the front surface of the liquid crystal display panel 105, and accepts pressing operations by a user. Since the touch panel is pressed, the liquid crystal display panel 105 including the touch panel requires certain strength.

A plurality of operation buttons 106 are arranged on a right end on the rear surface of the digital camera. When the operation buttons 106 are operated, an operation mode of the digital camera at the time of photography and reproduction can be switched, unnecessary captured images can be deleted, or various settings of the digital camera can be changed according to various operation screens displayed on the liquid crystal display panel 105.

As shown in FIG. 1C, a slide type power switch 107 is arranged on an upper surface of the digital camera. Further, a shutter button 108 and a zoom ring 109 are arranged on the upper surface of the digital camera. A pressing operation of the shutter button 108 enables capturing of still images and moving images. The zoom ring 109 is arranged around the shutter button 108, and can be rotated about the shutter button 108. When the zoom ring 109 is rotated, a zoom magnification is changed. At this time, a degree of extending of the lens barrel 101 changes. When the zoom magnification is large, the degree of the extending of the lens barrel 101 becomes large and the zoom magnification is small, the degree of the extending of the lens barrel 101 becomes small.

Speaker holes 110 are provided to the upper surface of the digital camera. When the digital camera receives the pressing operation of the shutter button 108 or the various operations of the operation buttons 106, the digital camera emits an electronic sound from an internal speaker. The electronic sound emitted from the internal speaker is released outside from the speaker holes 110.

As shown in FIG. 1D, a battery cover 111 is provided to a bottom surface of the digital camera. The battery cover 111 opens and closes a housing portion provided inside the digital camera. The battery cover 111 can be opened or closed toward a front side on the plane of drawing, and a battery and a memory card are housed in the housing portion. A tripod tapped hole 112 for fixing the digital camera to a tripod or the like is provided to a right end on the bottom surface of the digital camera.

As shown in FIG. 1E, a terminal cover 113 for hiding various terminals provided to the left side of the digital camera is provided to a left side surface of the digital camera. The terminal cover 113 can be opened or closed toward the front side on the plane of drawing. These terminals are provided for connecting the digital camera to external devices. For example, these terminals include a USB (Universal Serial Bus) terminal for connecting the digital camera to a personal computer to transmit captured images to the personal computer, and an HDMI (High Definition Multimedia Interface) terminal for displaying captured images on a television receiver with a large screen.

### 2. Unit Configuration

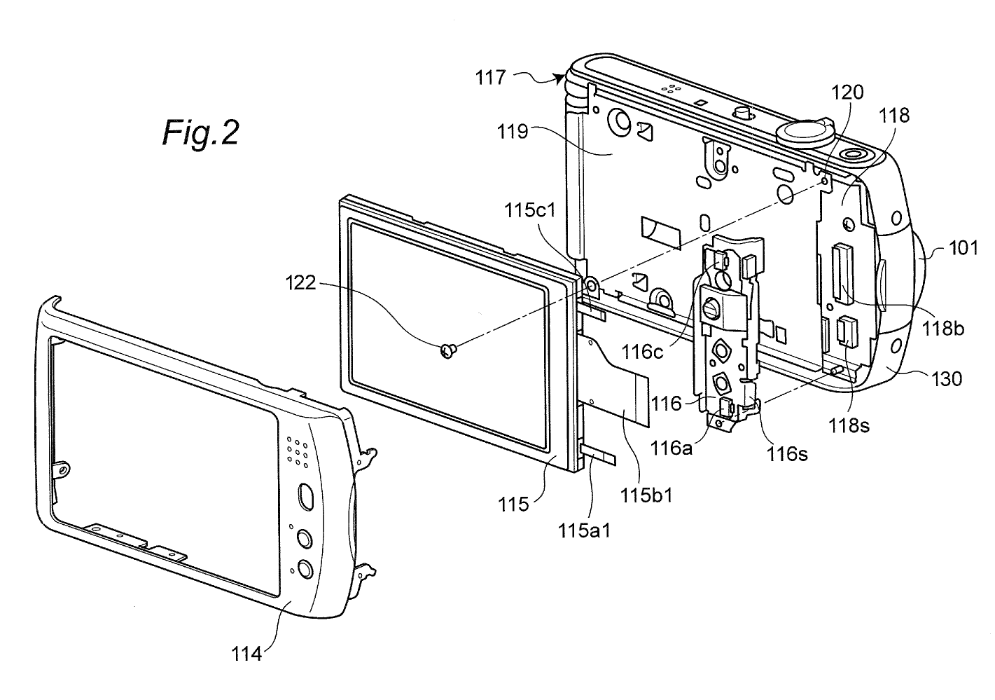

FIG. 2 is a first exploded perspective view showing the digital camera according to the embodiment. The digital camera generally includes a rear case 114, a liquid crystal display panel unit 115, a switch board 116, and a main body unit 117 housed in a front case.

The rear case 114 is made of metal such as aluminum or stainless steel. The liquid crystal display panel unit 115 houses a backlight, the liquid crystal display panel 105, and the touch panel with them stacked. A plurality of switches for converting a pressing operation and a sliding operation of the operation buttons 106 into electric signals are mounted on the switch board 116. The main body unit 117 includes the lens barrel 101, a housing section for housing the battery and the memory card, a main substrate 118 on which a power supply circuit, a control circuit, and a signal processing circuit are mounted, and the front case 130 that is made of metal such as aluminum or stainless steel and includes a sheet metal 119 and the like. The rear case 114 and the front case 130 may be made of resin or the like.

The switch board 116 has an extended section 116s configured with a flexible substrate. A connector 118s is mounted on the main substrate 118. The extended section 116s of the switch board 116 is connected to the connector 118s of the main substrate 118. A base on which the switch board 116 is placed is attached to a predetermined position of the main body unit 117 by a positioning pin. With such a configuration, when the pressing operation or the sliding operation is performed on the operation buttons 106, electric signal corresponding to the pressing operation or the sliding operation on the operation buttons 106 are transmitted to the control circuit mounted on the main substrate 118.

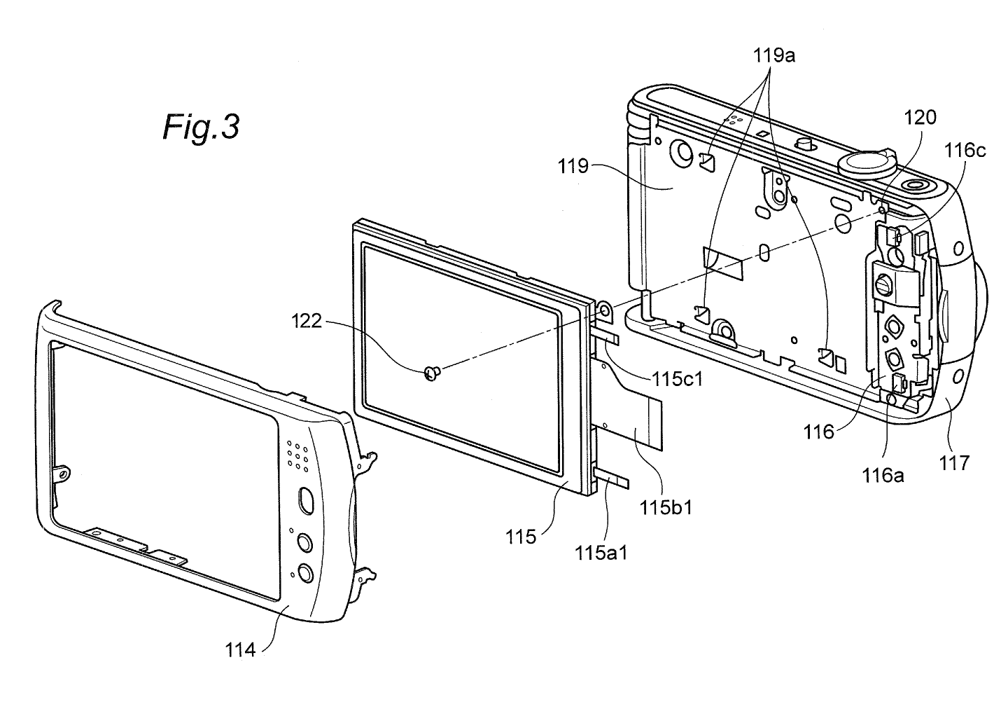

FIG. 3 is a second exploded perspective view showing the digital camera according to the embodiment. The switch board 116 is attached to the main body unit 117 in FIG. 3.

The liquid crystal display panel unit 115 is fixed to a screw hole 120 provided to the sheet metal 119, with a screw 122. The screw hole 120 of the sheet metal 119 serves also as a positioning (alignment) hole for the liquid crystal display panel unit 115 to the sheet metal 119. With this configuration, the liquid crystal display panel unit 115 can be fixed to the sheet metal 119 only with the screw 122, and can be suitably positioned. Details of a configuration of the liquid crystal display panel unit 115 are described below.

A flexible cable 115a1 for backlight, a flexible cable 151b1 for liquid crystal display panel, and a flexible cable 151c1 for touch panel extend from the liquid crystal display panel unit 115. The flexible cable 115a1 transmits power and a modulated light control signal to the backlight. The flexible cable 151b1 transmits power and a video signal to the liquid crystal display panel. The flexible cable 151c1 outputs a pressing signal of the touch panel. A terminal of the flexible cable 151a1 for backlight is connected to a connector 116a mounted on the switch board 116. A terminal of the flexible cable 115b1 for liquid crystal display panel is connected to a connector 118b mounted on the main substrate 118. A terminal of the flexible cable 151c1 for touch panel is connected to a connector 116c mounted on the switch board 116.

The above components are assembled in the following order. First, the terminal of the flexible cable 151b1 for liquid crystal display panel is connected to the connector 118b of the main substrate 118. Then, the liquid crystal display panel unit 115 is fixed to the screw hole 120 of the sheet metal 119 with the screw 122. Then, the extended section 116s of the switch board 116 is connected to the connector 118s of the main substrate 118. Then, the switch board 116 is attached to the predetermined position of the main body unit 117. Finally, the terminal of the flexible cable 151a1 for backlight and the terminal of the flexible cable 151c1 for touch panel are connected to the connector 116a and the connector 116c of the switch board 116.

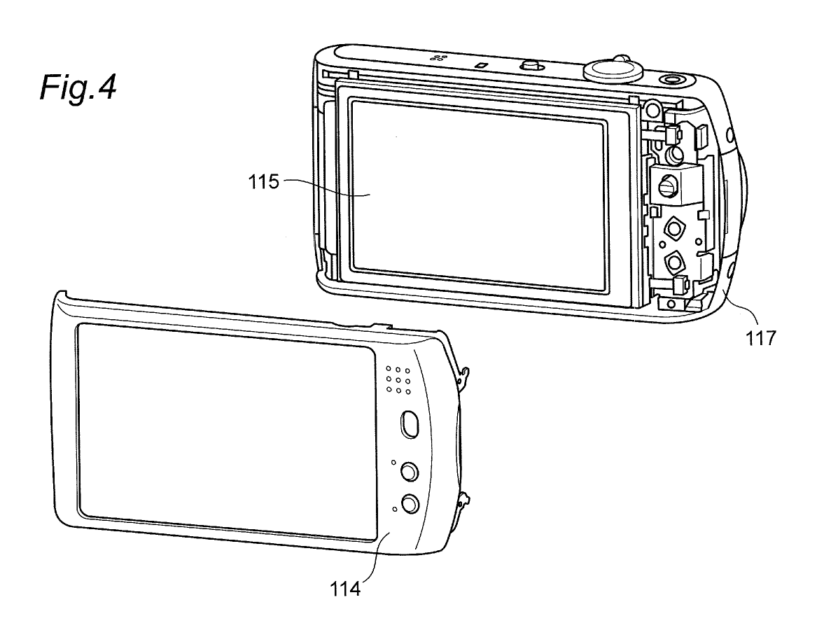

FIG. 4 is a third exploded perspective view showing the digital camera according to the embodiment. The liquid crystal display panel unit 115 is attached to the main body unit 117 in FIG. 4. When the rear case 114 is attached to the main body unit 117, the digital camera is completed.

### 3. Cross Section

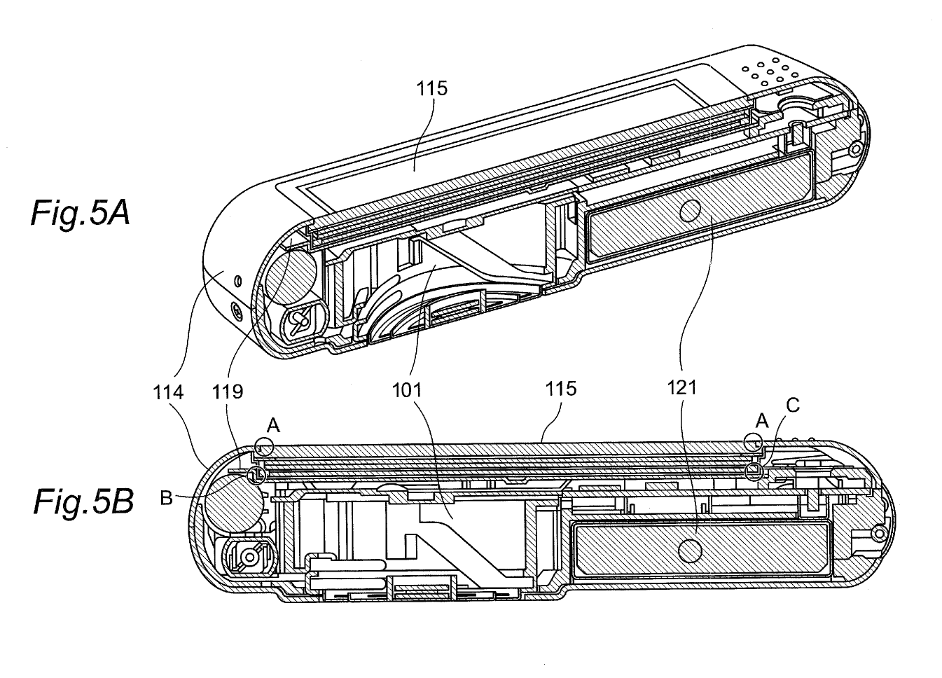

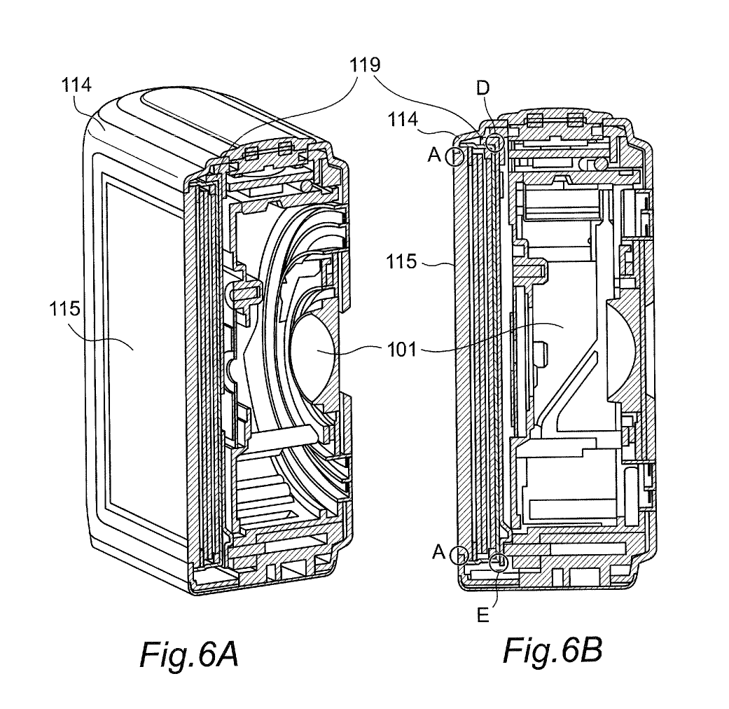

FIGS. 5A and 5B are horizontal cross sectional views showing the digital camera according to the embodiment. FIG. 5A is a perspective cross-sectional view, and FIG. 5B is a cross sectional view. Both of FIGS. 5A and 5B show the cross sections of the digital camera in the same cross-sectional positions at a portion near the upper surface of the digital camera. The lens barrel 101 occupies most of the right side portion in the digital camera (in FIG. 5, a left side portion), and a battery 121 occupies most of the left side portion in the digital camera (in FIG. 5, a right side portion). FIGS. 6A and 6B are vertical cross sectional views showing the digital camera according to the embodiment. FIG. 6A is a perspective cross-sectional view, and FIG. 6B is a cross sectional view. Both of FIGS. 6A and 6B show the cross sections in the same cross-sectional positions at the portion of the lens barrel 101.

The liquid crystal display panel unit 115 is placed on the sheet metal 119. A clearance (a portion shown by a circular mark A in FIGS. 5A and 5B) is provided between the edges of surfaces side of four edges of a touch panel 115c (described later) of the liquid crystal display panel unit 115 and edges of an opening provided to the rear case 114. The clearance is very narrow, and thus it is not shown in FIGS. 5A and 5B. A coefficient of thermal expansion of the rear case 114 made of metal is different from a coefficient of thermal expansion of the touch panel 115c of liquid crystal display panel unit 115 which is made of resin. At high temperature, size of the rear case 114 made of metal scarcely changes, while the touch panel 115c made of resin expands. For this reason, if the clearance is not provided, when the touch panel 115c and the liquid crystal display panel unit 115 are assembled, the touch panel 115c would run onto the rear case 114. By providing the clearance, above problem is solved. A rear side of the liquid crystal display panel unit 115 is positioned by a step of the sheet metal 119 as shown by a circular mark B. A rear and right side of the liquid crystal display panel unit 115 is positioned by a structure in the rear case 114 as shown by a circular mark C. A rear and upper side of the liquid crystal display panel unit 115 is positioned by a bent portion of the sheet metal 119 as shown by a circular mark D (see FIGS. 6A and 6B). A rear and lower side of the liquid crystal display panel unit 115 is positioned by a structure in the rear case 114 as shown by a circular mark E (see FIG. 6B).

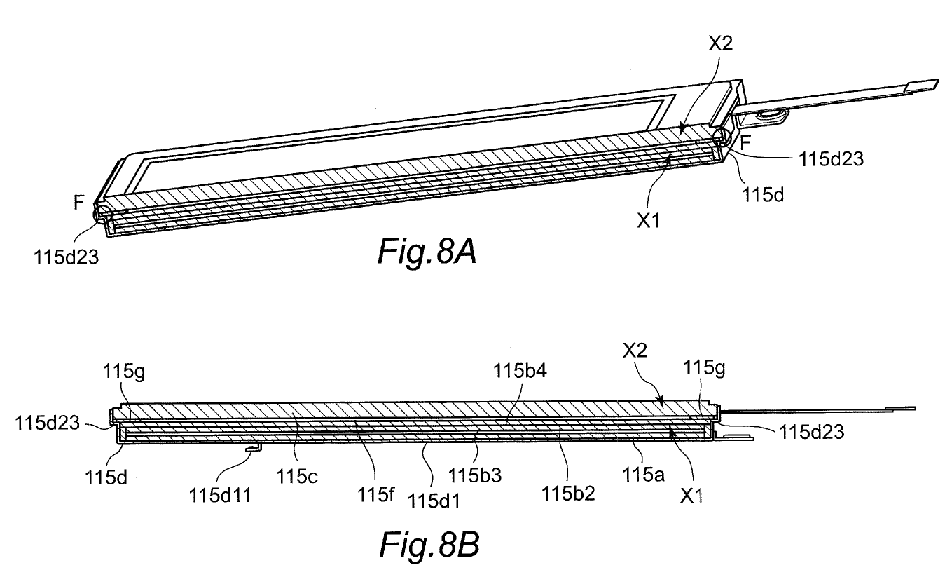

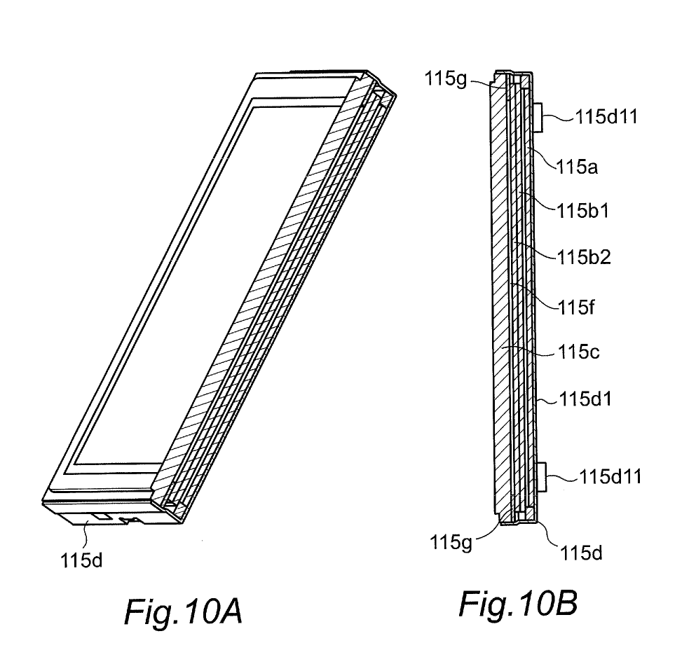

In the state that the liquid crystal display panel unit 115 is positioned, three hooks 115d11 (see FIGS. 8B and 10B referred later) are engaged with three hole sections 119a (see FIG. 3). The hooks 115d1 are provided on a surface opposite to the liquid crystal display panel in a bottom surface 115d1 of a frame 115d forming the liquid crystal display panel unit 115. The hole sections 119a are provided to the sheet metal 119. As a result, the liquid crystal display panel unit 115 is temporarily fixed to the sheet metal 119 to keep a position thereof until the screw 122 is fixed to fix the rear case 114.

### 4. Liquid Crystal Display Panel Unit

### 4-1. Perspective View

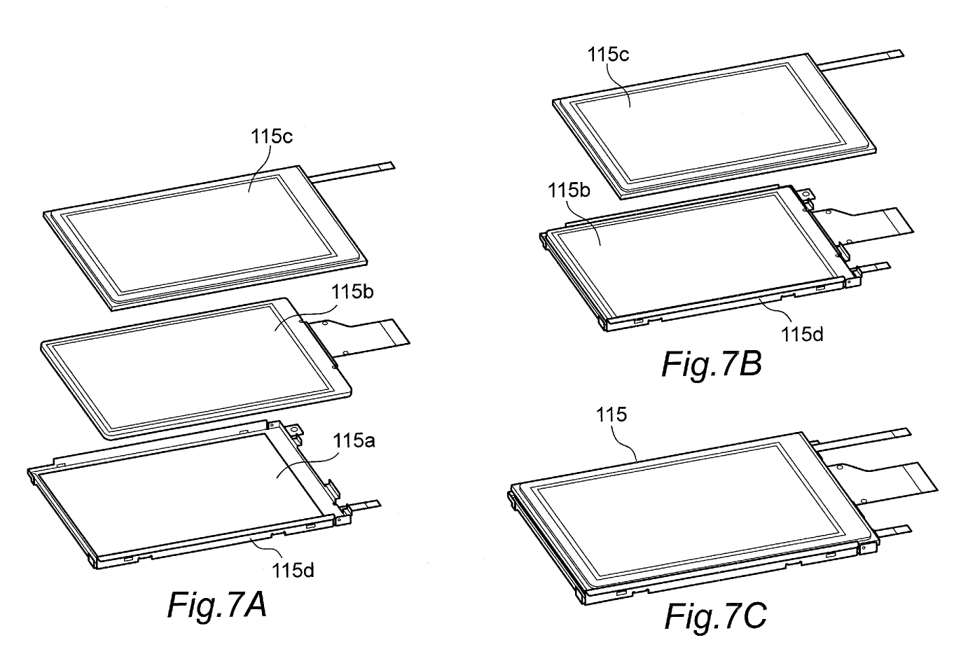

FIGS. 7A to 7C are exploded perspective views showing the liquid crystal display panel unit 115 according to the embodiment. FIG. 7A shows a state that the liquid crystal display panel unit 115 is disassembled into the frame 115d on which a backlight 115a is placed, a liquid crystal display panel 115b, and a touch panel 115c. FIG. 7B shows a state that the liquid crystal display panel unit 115 is disassembled into the frame on which the backlight 115a and the liquid crystal display panel 115b are placed, and the touch panel 115c. FIG. 7C is a perspective view showing the liquid crystal display panel unit 115 as a completed product.

The liquid crystal display panel unit 115 is structured so that the backlight 115a, the liquid crystal display panel 115b, and the touch panel 115c are stacked and housed in the frame 115d made of metal.

### 4-2. Cross Sectional View

FIGS. 8A and 8B are horizontal cross sectional views showing the liquid crystal display panel unit 115 according to the embodiment. FIG. 8A is a perspective cross-sectional view, and FIG. 8B is a cross sectional view. Both of FIGS. 8A and 8B show cross sections in the same cross-sectional positions at an upper portion of the liquid crystal display panel unit 115.

The liquid crystal display panel unit 115 is structured so that the backlight 115a, the liquid crystal display panel 115b, and the touch panel 115c are stacked and housed in the frame 115d made of metal. The liquid crystal display panel 115b is structured so that a liquid crystal layer 115b4 is sandwiched between a rear surface glass substrate 115b2 and a front surface glass substrate 115b3. A horizontal polarization filter is attached to the rear surface glass substrate 115b2, and a vertical polarization filter is attached to the front surface glass substrate 115b3.

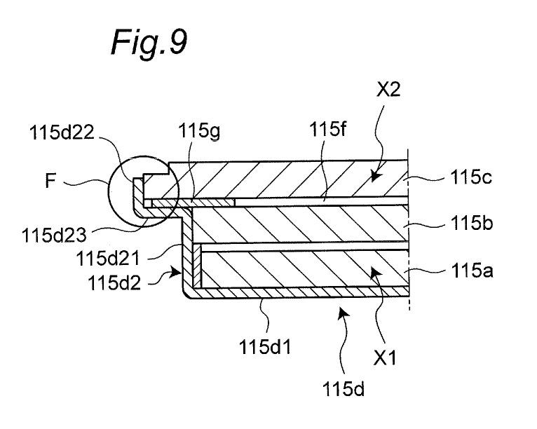

FIG. 9 is an enlarged view showing a left end portion of the liquid crystal display panel unit 115 in the horizontal cross section according to the embodiment. A right end portion of the liquid crystal panel has the same structure as the left end portion (the right end portion is not described in the drawings). The frame 115d has a bottom portion 115d1 and a side wall portion 115d2 which rises from an edge of the bottom portion 115d1, and is formed to be box-shaped where an upper surface is opened. The side wall portion 115d2 is formed to be a step-shaped so that an upper portion of the side wall portion 115d2 protrudes outward. The side wall portion 115d2 has a lower side wall portion 115d21, upper side wall portion 115d22 which is positioned outer than the lower side wall portion 115d21, and a step portion which connect the lower side wall portion 115d21 to the upper side wall portion 115d22 indicated by the circular mark F. In an internal space formed by the bottom portion 115d1 and the side wall portion 115d2, a space formed by the bottom portion 115d1 and the lower side wall portion 115d2 (a space that is closer to the bottom portion 115d1 than the step portion 115d23 indicated by the circular mark F) forms a first housing section X1, and a space other than the first housing section X1 (a space that is closer to an opening of the frame 115d) than the step portion 115d23 indicated by the circular mark F) forms a second housing section X2. The first housing section X1 houses the backlight 115a and the liquid crystal display panel 115b. The second housing section X2 houses the touch panel 115c. An end of the touch panel 115c is adhered to the step portion 115d23 by a double-faced tape 115g. In this housing state, an end of the touch panel 115c abuts a upper side wall section 115d22 at an end of the step portion. As a result, the touch panel 115c is positioned (aligned) with respect to the frame 115d and the liquid crystal display panel 115b.

Horizontal and vertical lengths of the touch panel 115c are longer than those of the liquid crystal display panel 115b. This is because an approximately entire region of a display section of the liquid crystal display panel 115b can be seen through in a state that the touch panel 115c is stacked on the liquid crystal display panel 115b. The touch panel 115c is adhered and fixed to the step portion 115d23 indicated by the circular mark F and a peripheral edge of the liquid crystal display panel 115b by the double-faced tape 115g. At this time, a gap 115f is formed between the liquid crystal display panel 115b and the touch panel 115c.

FIGS. 10A and 10B are vertical cross sectional views showing the liquid crystal display panel unit according 115 to the embodiment. FIG. 10A is a perspective cross-sectional view, and FIG. 10B is a cross sectional view. Both of FIGS. 10A and 10B show the cross sections in the same cross-sectional positions near the lens barrel 101.

In the liquid crystal display panel unit 115 according to the embodiment shown in FIGS. 10A and 10B, the step portion 115d23 indicated by the circular mark F is provided in the side wall portions of a left and right edges, but the similar step portion is not provided in side wall portions of a top and bottom edges.

### 5. Effect

### 5-1. Effect in Assembly

As a conventional display panel unit, for example, there is a panel unit which is unitized, by housing only the backlight and the liquid crystal display panel into the frame, with the touch panel attached to the liquid crystal display panel of this unit in a separate step. In this conventional unit, however, a jig or the like should be used in positioning (aligning) the touch panel when the touch panel is attached to the liquid crystal display panel.

When a user touches a certain target displayed on the liquid crystal display panel via the touch panel, a position coordinate of the touched target on the liquid crystal display panel and a position coordinate represented by a pressing signal from the touch panel should accurately correspond to each other. Therefore, the touch panel should be accurately positioned (aligned) with respect to the liquid crystal display panel.

In the liquid crystal display panel unit 115 according to the embodiment, the backlight 115a and the liquid crystal display panel 115b are housed in the first housing section X1 of the frame 115d, and the touch panel 115c is housed in the second housing section X2 of the frame 115d. As a result, the liquid crystal display panel 115b is positioned (aligned) by the first housing section X1 of the frame 115d, and the touch panel 115c is positioned (aligned) by the second housing section X2 of the frame 115d. Therefore, the touch panel 115c can be accurately and easily positioned (aligned) with respect to the liquid crystal display panel 115b without using a jig or the like.

Further, in the liquid crystal display panel unit 115 according to the embodiment, the frame 115d is made of metal. Further, the side wall portion 115d2 of the frame 115d2 is made a step-shaped so that the upper portion of the side wall portion 115d2 protrudes outward, the second housing section X2 that houses the touch panel 115c is provided. The second housing section X2 facilitates the positioning (aligning) when the liquid crystal display panel unit 115 is attached to the main body unit 117. Further, it is possible to position (align) the touch panel in the direction of the display surface/rear surface (a front-back direction, an optical axis direction of the lens).

The frame can be made of resin or the like, and a notch for second housing section can be provided. However, according to recent miniaturization of digital cameras and enlargement of the liquid crystal display panel, a portion forming a circumference of liquid crystal display panels (a portion so-called “casing frame”) is demanded to be narrowed as much as possible. That is, the frame is demanded to as narrow as possible.

In the liquid crystal display panel unit 115 according to the embodiment, since the frame 115d is made of metal, the frame 115d can be thinned. Since the step portion 115d23 indicated by the circular mark F is provided only to side wall portion of right and left sides of the frame 115d, the vertical length of the liquid crystal display panel unit 115 need not be lengthened more than necessary. Needless to say, if there is enough space in the vertical direction, a step portion may be provided to the up and down sides. A determination as to whether the step portion is provided to the side wall portion of the right and left side, the up and down sides, or to both of the right and left sides and the up and down sides may be appropriately made according to characteristics of an electronic device that adopts the liquid crystal display panel unit according to the embodiment.

Further, since the touch panel 115c is adhered to the liquid crystal display panel 115b by using the double side tape 115g, the gap 115f (see FIGS. 8B, 9 and 10B) having a thickness of the double sided tape 115g is formed between the liquid crystal display panel 115b and the touch panel 115c. Therefore, a force of the pressing operation of the touch panel 115c that is applied directly to the liquid crystal display panel 115b can be reduced.

These effects relating to the assembly are also effective in manufacturing and repairing of the digital camera according to the embodiment.

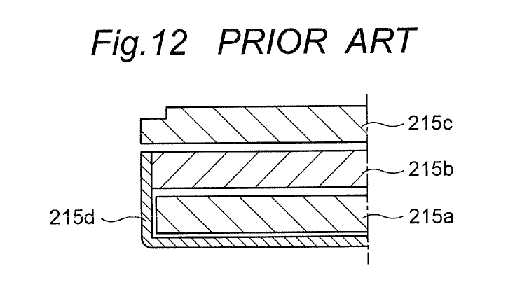

Further, there is a problem that since the touch panel is transparent, if dust invades between the liquid crystal display panel and the touch panel, the dust is visually recognized through the touch panel. This causes deterioration in product quality of the digital camera and deterioration in visibility of the liquid crystal display panel. In the conventional liquid crystal display panel unit, as shown in FIG. 12, the liquid crystal display panel 215b and backlight are housed in the frame 215d to be united, but touch panel 215c is not included in the unit. As a result, the touch panel 215c has to be adhered to the united liquid crystal display panel 215b. However, in the conventional configuration, it is difficult to position (align) the touch panel 215c to the liquid crystal display panel unit. Therefore, in the conventional liquid crystal display panel unit, the step of attaching the touch panel to the liquid crystal display panel unit should be performed in the step of attaching the liquid crystal display panel unit 115 to the main body unit 117 as well as the step of attaching the liquid crystal display panel unit 115 to the main body unit 117 in the clean room. Therefore, in the conventional liquid crystal display panel unit, the step of attaching the touch panel to the liquid crystal display panel unit should be performed in a clean room as well as the step of attaching the liquid crystal display panel unit 115 to the touch panel to the main body unit 117.

In the liquid crystal display panel unit 115 according to the embodiment, the backlight 115a and the liquid crystal display panel 115b are housed in the first housing section X1 of the frame 115d, and the touch panel 115c is housed in the second housing section X2 of the frame 115d. Therefore, only the step of assembling the liquid crystal display panel unit 115 may be performed in the clean room, and the step of attaching the liquid crystal display panel unit 115 to the main body unit 117 does not have to be performed in the clean room. The step of assembling the liquid crystal display panel unit 115 can be performed in a comparatively small line. Therefore, a scale of the necessary clean room can be made small.

### 5-2. Effect by Metal Frame

Since the pressing operation is premised on being performed on the touch panel, the liquid crystal display panel unit that accepts the pressing operation requires certain strength.

The liquid crystal display panel unit 115 according to the embodiment adopts the frame 115d made of metal, and the sheet metal 119 holds the entire surface of the liquid crystal display panel unit 115. For this reason, sufficient strength can be secured for the pressing operation of the touch panel 115c. Since the step portion 115d23 indicated by the circular mark F in the FIG. 9 is provided to the side wall 115d of the frame 115d, the strength of the frame 115d is further improved. Further, the strength of the frame 115d is suitably secured, whereas the frame 115d can be thinned. As a result, the enlargement of the liquid crystal display panel unit 115 can be avoided.

Since the frame 115d and the sheet metal 119 are made of metal, the frame 115d and the sheet metal 119 can be used also as electric grounding members. As a result, electric charges of electrostatic discharge into the digital camera can be effectively absorbed by and diffused, and the risk of breakdown of the power supply circuit, the control circuit, the signal processing circuit, and the like mounted on the main substrate 118 can be reduced. Further, electromagnetic waves radiated from the power supply circuit, the control circuit, the signal processing circuit, and the like mounted on the main substrate 118 can be effectively shielded. Therefore, electromagnetic waves radiated to the outside of the digital camera can be reduced. The frame 115d can be used also as a heat sink that absorbs and radiates heat generated from the imaging device in the digital camera and the control circuit, the signal processing circuit, and the like mounted on the main substrate 118.

Meanwhile, an external force to be applied to the liquid crystal display panel unit is not limited to an external force generated by the pressing operation of the touch panel. In the small-sized electronic device such as the digital camera that is premised on being carried, even if a strap is attached, the risk of being dropped cannot be completely eliminated. If the digital camera is dropped particularly in a state in which the lens barrel is extended and faced down, the liquid crystal display panel unit receives a direct impact of the drop.

In the digital camera according to the embodiment, the liquid crystal display panel unit 115 included in the frame 115d made of metal is arranged at the back surface side of the lens barrel 101. As a result, even if the digital camera drops in the state in which the lens barrel 101 is extended and faced down, a possibility of a damage of the liquid crystal display panel 115b can be reduced.

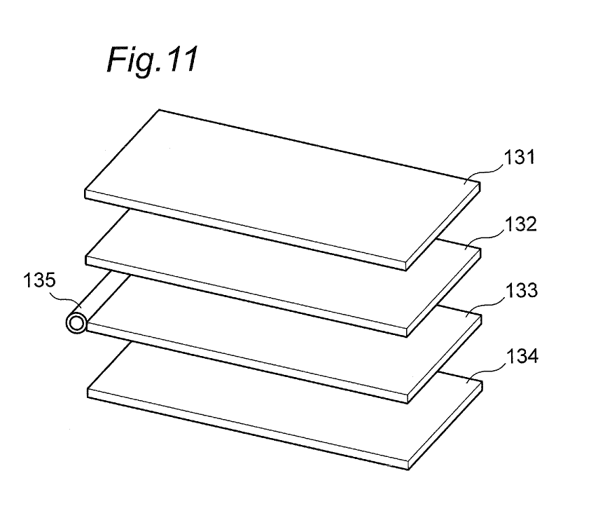

One example of a structure of the backlight 115a will be described. FIG. 11 is an exploded perspective view showing the backlight 115a. The backlight 115a has a light source 135, a reflection plate 134, a light-guiding plate 133, a diffusion plate 132, and a prism sheet 131. These components are housed in the first housing section X1 of the frame 115d in a state that the reflection plate 134, the light-guiding plate 133, the diffusion plate 132 and the light source 135, and the prism sheet 131 are stacked in this order. The frame 115d houses the components of the backlight 115a. Various configurational elements 131 to 134 which configure the backlight are positioned (aligned) by the frame 115d. In the present embodiment, as described above, the touch panel 115c is housed by utilizing the frame 115d for housing the components of the backlight 115a.

### 5-3. Others

In the liquid crystal display panel unit 115 according to the embodiment, the first housing section X1 houses the backlight 115a and the liquid crystal display panel 115b, and the second housing section X2 houses the touch panel 115c. However, instead of the touch panel 115c, a protective panel may be housed in the second housing section X2. As a result, the digital camera adopting the touch panel 115c and the digital camera that does not adopt the touch panel 115c can be easily manufactured in a separate manner. Further, instead of the touch panel 115c, an antireflection panel may be housed in the second housing section X2, or a liquid crystal shutter for displaying a three-dimensional image may be housed in the second housing section X2.

Similarly, instead of the liquid crystal display panel 115b, an organic EL panel may be housed in the first housing section X1. Since the organic EL panel is a light-emitting display panel, the backlight 115a is not necessary. Further, when a liquid crystal display panel that is not a transmission type but a reflection type is adopted, the backlight 115a is not necessary.

### INDUSTRIAL APPLICABILITY

The present embodiments can provide an electronic device having a display panel unit of which assembly is easy and of which quality is not deteriorated even if the touch panel is disposed on the front surface of the display panel. For this reason, the idea of the present embodiment can be widely applied to the electronic devices having the display panel, such as digital cameras, digital video cameras, PDAs (Personal Digital Assistants), photo viewers, portable television sets, and mobile telephones.

What is claimed is:

1. A display panel unit comprising:
a display panel;
a panel-shaped member having a portion of which an outside size is larger than that of the display panel; and
a metal frame having a first housing section configured to house the display panel and a second housing section configured to house the panel-shaped member with the panel-shaped member stacked on the display panel; wherein
the metal frame has a bottom portion and a side wall portion configured to rise from an edge of the bottom portion, and is box-shaped so that an upper side of the metal frame is open, and the side wall portion is formed to be step-shaped so that an upper portion of the side wall portion protrudes outward, and
in an internal space formed by the bottom wall portion and the side wall portion of the metal frame, the first housing section is defined by a space formed by the bottom wall portion and a portion of the side wall potion other than the upper portion, and the second housing section is defined by a space other than the first housing section.

2. The display panel unit according to claim 1, wherein only a predetermined portion of the upper potion of the side wall portion is formed to be step-shaped.

3. The display panel unit according to claim 1, wherein the panel-shaped member is a touch panel.

4. The display panel unit according to claim 1, wherein
the display panel comprises a liquid crystal panel and a backlight including a plurality of members stacked on the liquid crystal panel, and
the metal frame includes a frame configured to house the plurality of members composing the backlight.

5. An electronic device comprising the display panel unit according to claim 1.

6. An electronic device comprising:
the display panel unit according to claim 1, wherein
the metal frame is connected to an electric grounding.

7. An electronic device comprising:
the display panel unit according to claim 1, wherein
the metal frame is a heat radiating member.

8. An electronic device comprising:
a protrusion portion configured to protrude outside of a case and provided to a front surface of the electronic device; and
the display panel unit according to claim 1, the display panel provided on the back surface of the electronic device.
